(19) United States
(12) Patent Application Publication
(10) Pub. No.: US 2016/0276546 A1
(43) Pub. Date: Sep. 22, 2016

(54) CHIP PACKAGE STRUCTURE AND METHOD OF MANUFACTURING THE SAME

(71) Applicant: Genesis Photonics Inc., Tainan City (TW)

(72) Inventors: Hao-Chung Lee, Tainan City (TW); Chin-Hua Hung, Tainan City (TW); Cheng-Wei Hung, Tainan City (TW); Jui-Fu Chang, Tainan City (TW); Yu-Feng Lin, Tainan City (TW)

(21) Appl. No.: 15/073,672

(22) Filed: Mar. 18, 2016

Related U.S. Application Data
(60) Provisional application No. 62/134,577, filed on Mar. 18, 2015.
(60) Provisional application No. 62/157,450, filed on May 5, 2015.
(60) Provisional application No. 62/220,249, filed on Sep. 18, 2015.

(30) Foreign Application Priority Data
Aug. 5, 2015 (TW) 104125435
Mar. 10, 2016 (TW) 105107287

(51) Int. Cl. H01L 33/50; H01L 21/78; H01L 33/54; H01L 33/48; H01L 25/075; H01L 33/62

(52) U.S. Cl. CPC H01L 33/502; H01L 25/0753; H01L 33/62; H01L 33/54; H01L 33/483; H01L 21/78; H01L 2933/0066; H01L 2933/005; H01L 2933/0041

(57) ABSTRACT

A chip package structure and method of manufacturing the same are provided. The chip package structure includes a substrate with a carrier surface, a chip having a first surface and a second surface positioned oppositely and a side surface connecting the first surface and the second surface, an encapsulation layer and a fluorescent layer. The second surface of the chip is disposed on the carrier surface of the substrate. The fluorescent layer fully covers the first surface of the chip. The encapsulation layer covers the carrier surface of the substrate and the side surface of the chip. A reflectivity of the encapsulation layer is at least greater than 90%.

### CROSS-REFERENCE TO RELATED APPLICATION

The application claims the priority benefits of U.S. provisional application Ser. No. 62/134,577, filed on Mar. 18, 2015, U.S. provisional application Ser. No. 62/157,450, filed on May 5, 2015, U.S. provisional application Ser. No. 62/220,249, filed on Sep. 18, 2015, Taiwan application serial no. 104125435, filed on Aug. 5, 2015 and Taiwan application serial no. 105107287, filed on Mar. 10, 2016. The entirety of each of the above-mentioned patent applications is hereby incorporated by reference herein and made a part of this specification.

### FIELD OF THE INVENTION

The invention relates to a chip package structure and a method of manufacturing the same. More particularly, the disclosure relates to a light-emitting diode (LED) chip package structure capable of improving light conversion and extraction efficiency and a method of manufacturing the same.

### DESCRIPTION OF RELATED ART

Light-emitting diodes (LEDs) capable of saving energy and protecting the environment can be applied widely to not only daily life products that can be seen everywhere, such as general lighting fixtures, but also displays of computers or mobile electronic products, art works and applications, etc.

Generally speaking, in a conventional LED chip package structure, an LED chip is disposed on a on a concave cup type carrier substrate formed of a ceramic or a metal material and then encapsulated by molding compound to form a package structure. In this circumstance, electrodes of the LED chip are located in the concave cup and above the miler substrate. However, the concave cup type carrier substrate has a specified shape and thickness, such that the thickness of the LED chip package structure cannot effectively reduced. Moreover, in order to satisfy various application demands, such as emitting light to achieve various color temperatures, different concave cup type miler substrate, e.g., substrates with various thicknesses, are employed. Thus, the conventional light emitting diode (LED) chip package structure has limited flexibility for application.

### SUMMARY

The application provides a chip package structure capable of enhancing optical properties (e.g., light conversion and extraction efficiency) of the chip package structure and a method of manufacturing the same.

According to an embodiment of the disclosure, a chip package structure including a substrate with a carrier surface, a chip having a first surface and a second surface which are opposite to each other and a side surface connecting the first surface and the second surface, an encapsulation layer and a fluorescent layer is provided. The second surface of the chip is disposed on the carrier surface of the substrate. The fluorescent layer fully covers the first surface of the chip. The encapsulation layer covers the carrier surface of the substrate and the side surface of the chip. A reflectivity of the encapsulation layer is at least greater than 90%.

According to an embodiment of the disclosure, a method of manufacturing a chip package structure is provided. The method includes providing a substrate and separately disposing a plurality of chips on a carrier surface of the substrate, wherein each of the chips has a first surface and a second surface which are opposite to each other and a side surface connecting the first surface and the second surface, and the second surfaces are disposed on the carrier surface of the substrate; forming a fluorescent layer to fully cover the first surfaces of the chips; forming an encapsulation layer to cover the carrier surface of the substrate and the side surfaces of the chips, wherein a reflectivity of the encapsulation layer is at least greater than 90%; and dicing the encapsulation layer and the substrate to form a plurality of chip package structures.

To sum up, in the chip package structure and the method of manufacturing the same provided by the disclosure, after the chip is disposed on the substrate and packaged by the encapsulation layer, a surface of the chip is exposed, and the fluorescent layer is formed on the exposed surface of the chip, thereby, optical properties (e.g., the light conversion and extraction efficiency) of the chip package structure can be improved through designs of the embodiments. In other embodiments, the light-transmittance layer may be further selectively disposed on the fluorescent layer to serve as a light-transmittance protective layer, such that water vapor transmission paths may be increased, and the water vapor may be effectively prevent from penetrating in. Certainly, different structure types of the light-transmittance layer (for example, a lens light-transmittance layer) can facilitate effectively improving the light extraction efficiency.

To make the above features and advantages of the disclosure more comprehensible, embodiments accompanied with drawings are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIGS. 1A to 1D are schematic views illustrating a method of manufacturing a chip package structure according to a first embodiment of the disclosure.

FIGS. 2A to 2E are schematic views illustrating a method of manufacturing a plurality of chip package structures according to the first embodiment of the disclosure.

FIG. 3 is a schematic view illustrating a chip package structure according to the second embodiment of the disclosure.

FIG. 4 is a schematic view illustrating a chip package structure according to the third embodiment of the disclosure.

FIG. 5 is a schematic view illustrating a chip package structure according to the fourth embodiment of the disclosure.

FIG. 6 is a schematic view illustrating a chip package structure according to the fifth embodiment of the disclosure.

FIGS. 7A to 7C are schematic views showing an application example of the chip package structure in an in-line light source layout on the substrate.

FIGS. 8A to 8C are schematic views showing an application example of the chip package structure in a matrix light source layout on the substrate.

FIGS. 9A to 9C are schematic views illustrating part of the steps of a method of manufacturing a chip package structure according to the sixth embodiment of the disclosure.

FIGS. 10A to 10C are schematic views illustrating part of the steps of a method of manufacturing a chip package structure according to the seventh embodiment of the disclosure.

FIGS. 11A to 11E are schematic views illustrating part of the steps of a method of manufacturing a chip package structure according to the eighth embodiment of the disclosure.

FIGS. 12A to 12D are schematic views illustrating part of the steps of a method of manufacturing a chip package structure according to the ninth embodiment of the disclosure.

### DESCRIPTION OF EMBODIMENTS

The embodiments of the disclosure provides a chip package structure and a method of manufacturing the same capable of improving a light conversion and extraction efficiency. A plurality of embodiments will be provided below for describing the disclosure with reference to the accompanying drawings. It should be noted that the structure and contents set forth in the embodiments are merely for illustration, and the scope sought for protection by the disclosure is not limited to the aspects. The same reference numerals are used for representing the same or similar elements in the following embodiments. It should be noted that not all the feasible embodiments are illustrated in the disclosure. The structure as disclosed can be further changed and modified to meet the demands for actual applications, without departing from the spirit and the scope of the disclosure. Therefore, other implementation aspects that are not set forth in the disclosure can also be applied. Moreover, the drawings have been simplified for clearly illustrating the contents of the embodiments, and the size ratio on each drawing is not illustrated proportionally to the actual product. Thus, the specification and the drawings are provided merely for the illustrations of the embodiments, and shall not construe any limitations to the scope of the disclosure.

### First Embodiment

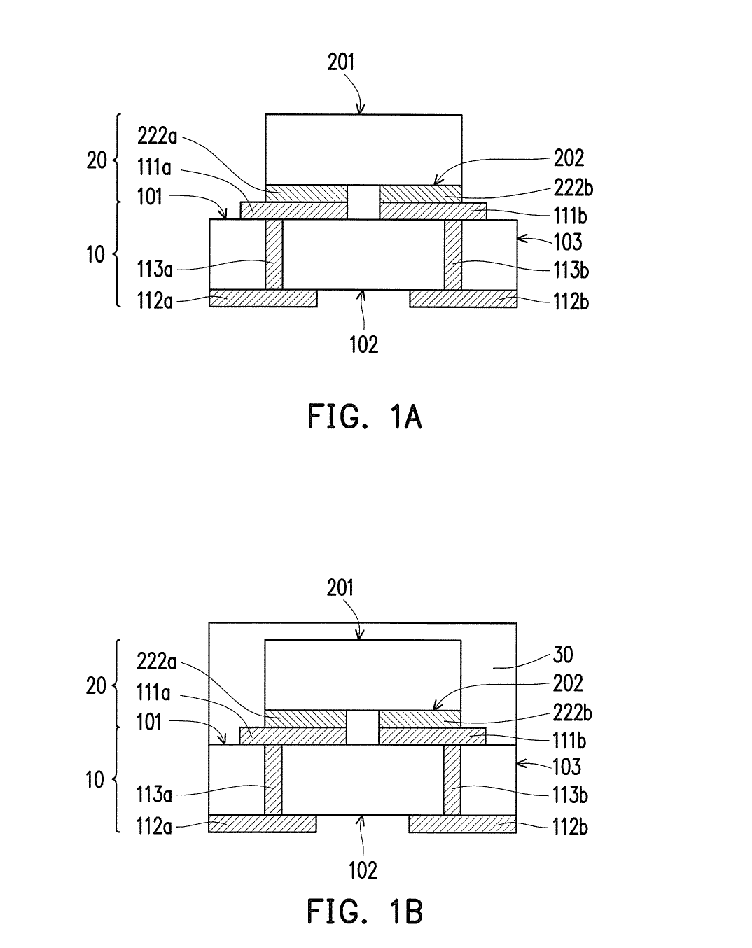

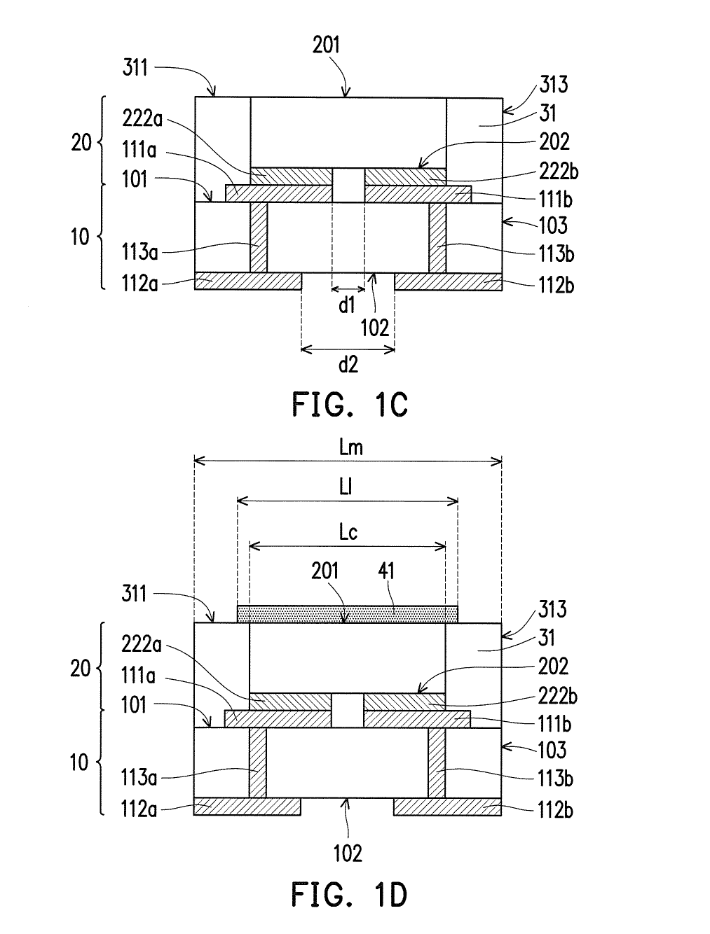

FIGS. 1A to 1D are schematic views illustrating a method of manufacturing a chip package structure according to a first embodiment of the disclosure. In FIGS. 1A to 1D, a cross-sectional view of a single chip package structure is illustrated in the description with respect to a manufacturing method thereof for better understanding of details related to each element. Referring to FIG. 1A, a substrate 10 is provided, and a chip 20 is disposed on a carrier surface 101 of the substrate 10. The chip 20 is, for example, a light emitting diode (LED) chip and has a first surface 201 and a second surface 202 which are opposite to each other. The second surface 202 is disposed on the carrier surface 101 of the substrate 10. The first surface 201 is a light-emitting surface of the chip 20.

In an embodiment, the chip 20 is a UV LED chip with an emission wavelength ranging from 315 nm to 412 nm. In another embodiment, the chip 20 is a blue LED chip with an emission wavelength ranging from 440 nm to 470 nm. LED chips with other emission wavelength ranges may also be applicable, and the disclosure is not limited thereto.

Referring to FIG. 1B, an encapsulation material 30 is formed on the carrier surface 101 of the substrate 10 and covers the carrier surface 101 and the chip 20. A reflectivity of the encapsulation material 30 is at least greater than 90%. In an embodiment, a material of the encapsulation material 30 includes, for example, a polymer material, such as white epoxy resin or silicon resin encapsulation glue (but the disclosure is not limited thereto), which has a high reflectivity characteristic for shielding side light and improving forward light emitting efficiency of the chip 20.

Then, referring to FIG. 1C, part of the encapsulation material 30 is removed to form an encapsulation layer 31. A top surface 311 of the encapsulation layer 31 exposes the first surface 201 of the chip 20, and the top surface 311 is co-planar with the first surface 201 of the chip 20. In the embodiment, the part of the encapsulation material 30 is removed by means of polishing, for example.

Additionally, in an embodiment, in the step of forming the encapsulation layer 31, the encapsulation material 30 which is removed by means of polishing contacts the first surface 201 of the chip 20, and then, the first surface 201 is also polished, such that the top surface 311 of the encapsulation layer 31 with the high reflectivity is co-plannar with the first surface 201 of the chip 20, and the first surface 201 (e.g., a transparent sapphire surface) of the chip 20 has scratches and becomes a roughened surface to increase light extraction. In an embodiment, the polished first surface 201 of the chip 20 has a surface roughness (center-line average roughness, Ra) greater than 0.01 μm.

In addition, through the carrying of the substrate 10 with high mechanical strength, when the part of the encapsulation material 30 is removed by means of polishing, not only the first surface 201 of the chip 20 is roughened, but also a transparent substrate (e.g., a sapphire substrate) of the chip 20 is simultaneously thinned, such that total reflection paths are reduced, and illumination is increased to reinforce the forward light intensity. Taking a 2-inch wafer for example, a thickness of the thinned chip 20 may be reduced to 100 μm in the manufacturing method provided in the embodiment. Certainly, the thickness value of the thinned chip 20 may be determined on conditions (e.g., the wafer size, the mechanical strength of the substrate 10 and so on) in actual applications and may be even less than 100 μm without causing fragment.

After the top surface 311 of the encapsulation layer 31 is co-plannar with the first surface 201 of the chip 20, a fluorescent layer 41 is formed above the top surface 311 of the encapsulation layer 31 and at least fully covers the first surface 201 of the chip 20. For example, the fluorescent layer 41 covers the first surface 201 of the chip 20, but is smaller than a side length of the encapsulation layer 31. In an embodiment, besides fully covering the first surface 201 of the chip 20, four side lengths of the fluorescent layer 41 are respectively smaller than four side lengths of the encapsulation layer 31. The fluorescent layer 41 may be formed by using, for example, a mask having a plurality of separately disposed openings, and the fluorescent layer 41 is coated by means of, for example, spraying, through the openings. In an actual manufacturing process, after the fluorescent layer 41 is formed, a plurality of separate single chip package structures may be formed through dicing the encapsulation layer 31 and the substrate 10, as illustrated in FIG. 1D. In an embodiment, the fluorescent layer 41 is doped with a plurality of fluorescence particles having a particle size ranging from 3 μm to 50 μm.

According to the embodiment, in addition to the top surface 311 of the encapsulation layer 31 being co-plannar with the first surface 201 of the chip 20, referring to FIG. 1D, the substrate 10 in the single chip package structure also has two side surfaces 103 respectively connected with the carrier surface 101, and the encapsulation layer 31 also has two side surfaces 313 respectively connected with the top surface 311. After the encapsulation layer 31 and the substrate 10 are diced, the two side surfaces 313 of the encapsulation layer 31 are co-plannar with the two side surfaces 103 of the substrate 10.

Moreover, it should be noted that the fluorescent layer 41 may also be directly formed on the top surface 311 of the encapsulation layer 31 (as illustrated in FIG. 1D), or the fluorescent layer 41 may be formed on a light-transmittance layer (made of a material which is not limited to a plastic material) after the light-transmittance layer is formed on the top surface 311 of the encapsulation layer 31 (which will be described in the fifth embodiment below), which is not limited in the disclosure and pertains to one of the implementation aspects of the disclosure as long as the fluorescent layer 41 is capable of at least fully covering the first surface 201 of the chip 20.

The single chip package structure of the embodiment is directly formed on the fluorescent layer 41 on the top surface 311 of the encapsulation layer 31 and has an area which is substantially equal to or greater than an area of the chip 20, but smaller than an area of the top surface 311 of the encapsulation layer 31. In an embodiment, referring to FIG. 1D, a side length L1 of the fluorescent layer 41 capable of fully covering the first surface 201 of the chip 20 is greater than a side length Lc of the chip 20, but smaller than a side length Lm of the encapsulation layer 31. Certainly, the disclosure is not limited thereto. In another embodiment, the area of the fluorescent layer 41 may also be substantially equal to or slightly greater than the area of the chip 20. Namely, the side length L1 of the fluorescent layer 41 may be substantially equal to or slightly greater than the side length Lc of the chip 20 to mitigate blue and/or yellow ring phenomenons, which pertains to one of the implementation aspects of the disclosure.

The chip 20 is repeatedly heated and cooled during the package process, or the packaged chip 20 causes thermal stress to generate at an interface between each packaging material layer having different coefficients of thermal expansion (CTEs) during the package process, which leads the packaging material layers to be deformed, peeled off, cracked, or even causes damage to the chip. Thus, in the embodiment, the better the smaller coefficients of thermal expansion (CTEs) the substrate 10 for disposing the chip 20 (e.g., a flip chip) and the encapsulation layer 31 covering and directly contacting the substrate 10, while the better the smaller difference between the CTEs, so as to prevent the thermal stress from causing undesirable damages to the structure. In an embodiment, the CTEs of both the encapsulation layer 31 and the substrate 10 are less than 15 ppm/° C. In an embodiment, the difference between the CTEs of the encapsulation layer 31 and the substrate 10 is less than 10 ppm/° C. In an embodiment, a ceramic substrate with a low CTE about 6 ppm/° C., for example, is selected for the substrate 10; while the encapsulation layer 31 is, for example, a white epoxy or silicon resin encapsulation glue with a low CTE, wherein the CTE of the silicon resin encapsulation glue is about 14 ppm/° C. In addition, the ceramic substrate has a high flexural strength and is capable of protecting the chip from being pulled and dragged by the stress, thereby functioning as a stress stopping layer.

Furthermore, a short circuit risk of the chip package structure of the embodiment may be lowered through the specific design of the substrate 10, and when being employed as a surface-mount device (SMD), the substrate 10 may facilitate increasing a surface-mount area, so as to improve alignment precision and assembly efficiency when the chip 20 is assembled with an external circuit. Referring to FIGS. 1A to 1D, the substrate 10 of the embodiment has a bottom surface 102 opposite to the carrier surface 101 and includes a plurality of extending electrodes 111a and 111b which are separated from each other and disposed on the carrier surface 101, a plurality of pads 112a and 112b which are separated from each other and disposed on the bottom surface 102 and a plurality of conductive vias 113a and 113b which are vertically formed in the substrate 10. The pads 112a and 112b are electrically connected with the extending electrodes 111a and 111b through the conductive vias 113a and 113b, such that the bottom surface 102 and the carrier surface 101 are conducted with each other. For example, the pad 112a is electrically connected with the extending electrode 111a through the conductive via 113a, and the pad 112b is electrically connected with the extending electrode 111b through the conductive via 113b.

The chip 20 includes a plurality of electrodes 222a and 222b which are separated from each other and disposed on the second surface 202. When the chip 20 is disposed on the carrier surface 101 of the substrate 10, the electrodes 222a and 222b of the chip 20 respectively contact the extending electrodes 111a and 111b of the substrate 10. Therein, the extending electrodes 111a and 111b may be disposed by entirely or partially overlapping the electrodes 222a and 222b, and any disposition manner as long as the extending electrodes 111a and 111b are structurally and electrically connected with the electrodes 222a and 222b of the chip 20 pertains to one of the implementation aspects of the disclosure.

As illustrated in FIGS. 1A to 1D, the extending electrodes 111a and 111b of the substrate 10 are separated from each other and expose part of the second surface 202 of the chip 20. Additionally, the pads 112a and 112b of the bottom surface 102 of the substrate 10 are separated from each other and extend toward the side surfaces 103 of the substrate 10. By utilizing the design of the extending electrodes 111a and 111b and the pads 112a and 112b of the substrate 10, a distance between the electrodes 222a and 222b of the chip 20 may be enlarged, so as to lower the short circuit risk. Referring to FIG. 1C, the two adjacent electrodes 222a and 222b of the chip 20 have a first spacing d1, the two pads 112a and 112b of the substrate 10 have a second spacing d2, and the second spacing d2 is greater than the first spacing dl. Additionally, areas of the extending pads 112a and 112b are greater than areas of the electrodes 222a and 222b of the chip 20, such that when the chip 20 is assembled, e.g., surface-mounted, with the external circuit, the surface-mount area of the entire chip package structure is increased, so as to increase the alignment precision and to improve the assembly efficiency. Specially, when the package structure has a quite small size, the design of the embodiment may further facilitate significant improvement in product yield, electric performance, and structural strength and stability of the package structure.

In addition, in the coating process of the fluorescent layer 41, a ratio range of ratio of phosphors and colloid may be adaptively selected according to different color temperatures, so as to obtain a preferable light conversion and extraction efficiency. For example, a fluorescent layer corresponding to a high color temperature has a first thickness, a fluorescent layer corresponding to a low color temperature has a second thickness, and the first thickness is less than the second thickness (the fluorescent layer corresponding to the high color temperature is thinner than the fluorescent layer corresponding to the low color temperature). In an embodiment, the thickness of the fluorescent layer 41 ranges from 40 μm to 100 μm as the color temperature ranges from 4500K to 9000K, and the fluorescent layer 41 includes polymer colloid and phosphors in a percent by weight ranging from 40 wt % to 60 wt % distributed in the polymer colloid. In an embodiment, the thickness of the fluorescent layer 41 ranges from 100 μm to 250 μm as the color temperature ranges from 2200K to 4000K, and the fluorescent layer 41 includes polymer colloid and phosphors in a percent by weight ranging from 40 wt % to 70 wt % distributed in the polymer colloid. The aforementioned values are merely examples for illustration, and construe no limitations to the disclosure. Comparatively, in the conventional chip package structure, the chip is disposed on a concave cup type carrier base, which also restricts the thickness variation of the fluorescent layer. In the structural design provided by the embodiments of the disclosure, the thickness of the fluorescent layer 41 may be correspondingly adjusted and changed based on different demands for the degrees of the color temperatures to be achieved to obtain the preferable light conversion and extraction efficiency. Thus, the design of the chip package structure of the embodiment has greater flexibility for selection in application variations in comparison with the convention chip package structure.

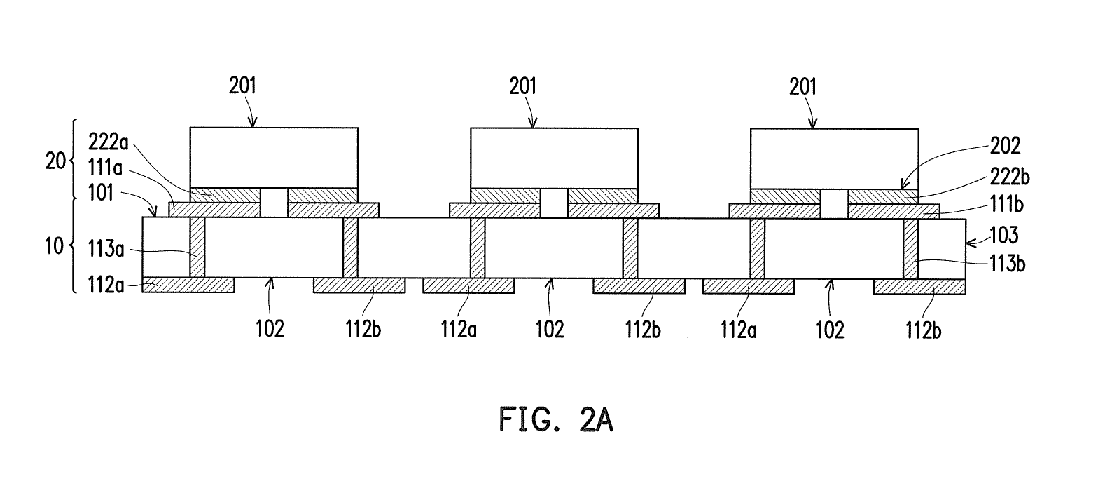

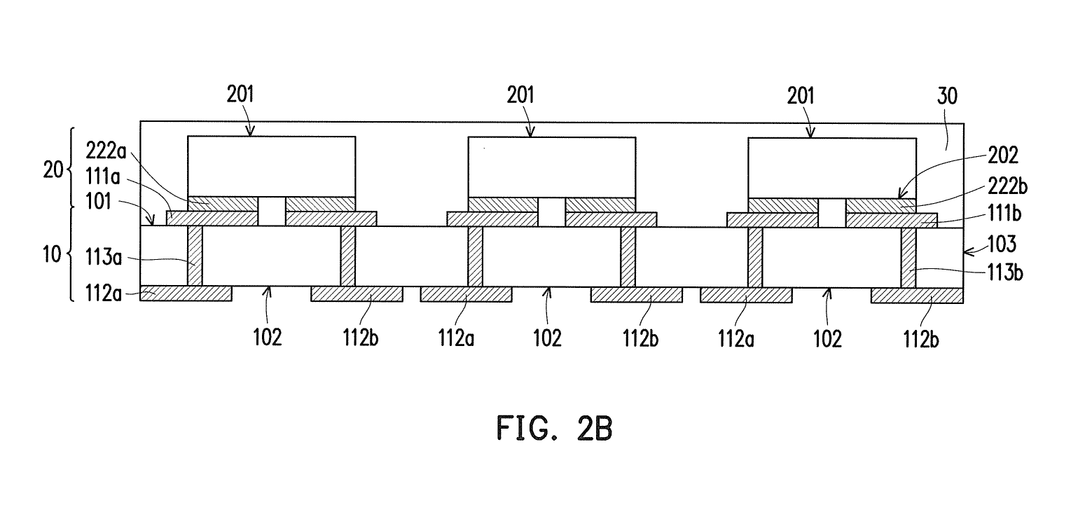

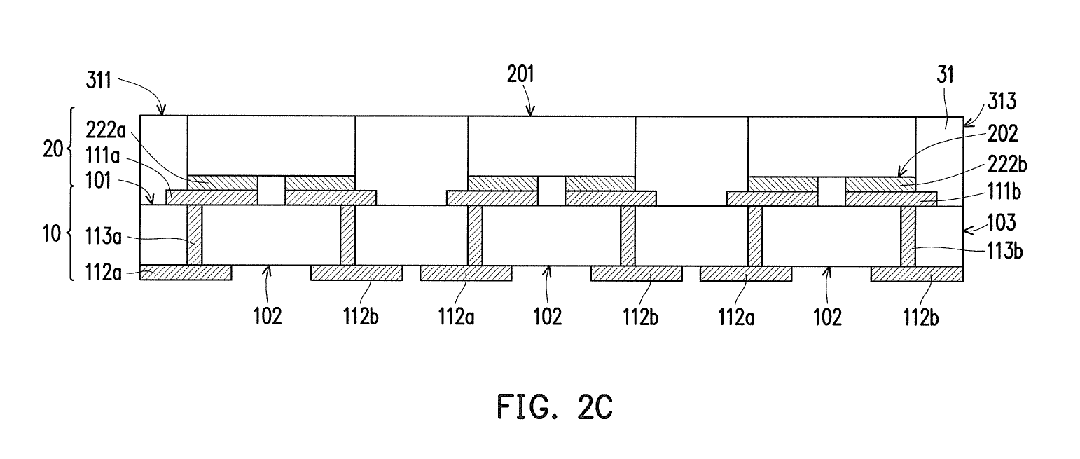

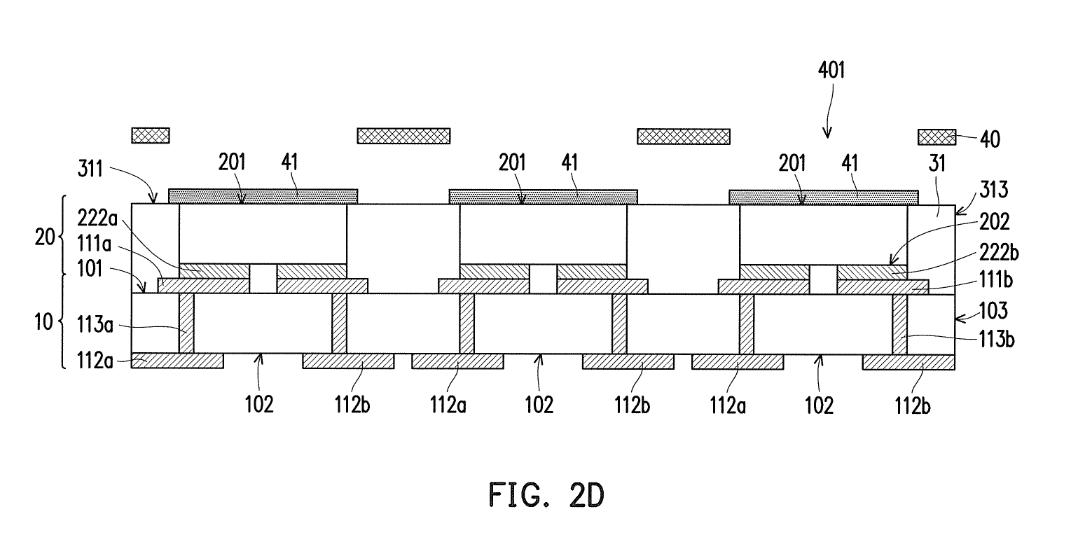

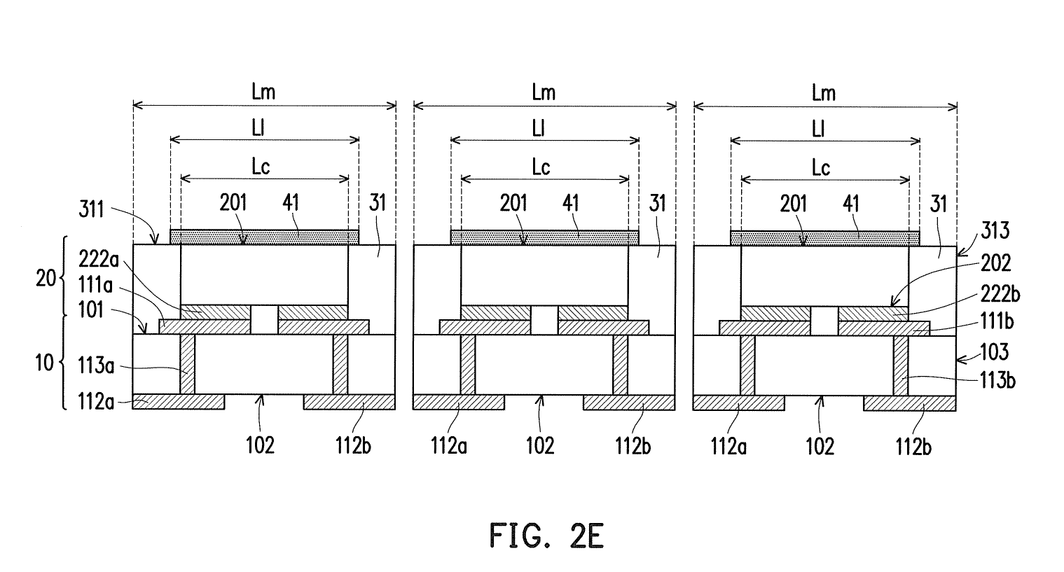

FIGS. 2A to 2E are schematic views illustrating a method of manufacturing a plurality of chip package structures according to the first embodiment of the disclosure. Detailed structures of each packaging material layer and related description may refer to the descriptions related to FIGS. 1A to 1D, and part of the details will not be repeated. Referring to FIG. 2A, a substrate 10 is provided, and a plurality of chips 20 are separately disposed on a carrier surface 101 of the substrate 10, wherein each chip 20 has a first surface (light-emitting surface) 201 and a second surface 202 (having electrodes 222a and 222b) which are opposite to each other, and the second surface 202 is disposed on the carrier surface 101 (having extending electrodes 111a and 111b) of the substrate 10. Referring to FIG. 2B, an encapsulation material 30 is formed on the carrier surface 101 of the substrate 10 and covers the carrier surfaces 101 and the chips 20. A reflectivity of the encapsulation material 30 is at least greater than 90%. Then, referring to FIG. 2C, part of the encapsulation material 30 is removed by means of, for example, polishing to form an encapsulation layer 31. During the polishing operation, steps, such as roughening the surface (i.e., the first surface 201) and thinning the chips may also be performed. After the polishing step is completed, a top surface 311 of the encapsulation layer 31 exposes the first surfaces 201 of the chips 20 and is and co-planar with the first surfaces 201 of the chips 20. Referring to FIG. 2D, a mask 40 is provided over the encapsulation layer 31, and the mask 40 has a plurality of openings 401 which are separately disposed and corresponding to positions of the chips 20. An area of each opening 401 is substantially greater than or equal to an area of each chip 20. A fluorescent layer 41 is coated above the top surface 311 of the encapsulation layer 31 through the openings 401 of the mask 40, and the fluorescent layer 41 at least covers the first surface 201 of each chip 20, but is smaller than a side length of the encapsulation layer 31. Thereafter, referring to FIG. 2E, the encapsulation layer 31 and the substrate 10 are diced to form a plurality of chip package structures. An area of the fluorescent layer 41 of each chip package structure (as illustrated in FIG. 1D) is substantially equal to or the area of each chip 20, but smaller than an area of the top surface 311 of each encapsulation layer 31. As illustrated in FIG. 1D, the side length L1 of the fluorescent layer 41 fully covering the chip 20 is greater than the side length Lc of the chip 20, but smaller than the side length Lm of the encapsulation layer 31. After the dicing step, the two side surfaces 313 of the encapsulation layer 31 are co-plannar with the two side surfaces 103 of the substrate 10.

Several type of chip package structure designs of the disclosure are provided below as examples for illustration. It should be noted that the disclosure is not limited to the implementation aspects of the illustrated examples, and other implementation aspects that are not illustrated in the disclosure may also be applied without departing from the scope sought for protection by the disclosure. Moreover, elements which are the same as or similar to those in the first embodiment use the same or similar referral numerals in the second to the fifth embodiments and detailed that are described will not be repeated hereinafter.

### Second Embodiment

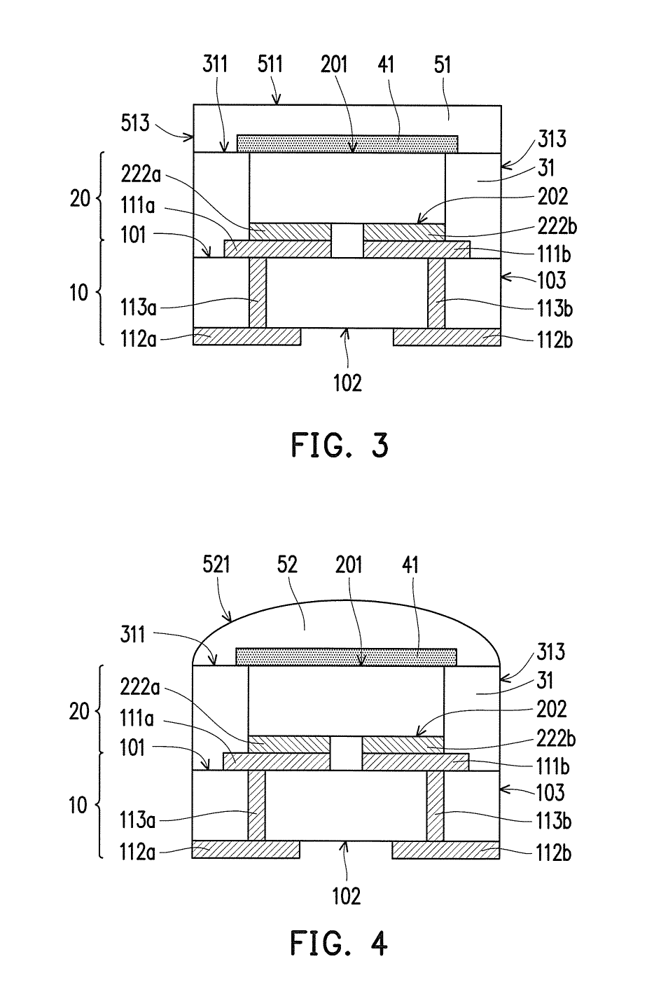

FIG. 3 is a schematic view illustrating a chip package structure according to the second embodiment of the disclosure. The second embodiment is different from the first embodiment in further forming light-transmittance layer 51 on the chip package structure illustrated in FIG. 1D. The light-transmittance layer 51 is made of a planar transparent plastic material in the second embodiment. Referring to FIG. 3, the fluorescent layer 41 of the second embodiment is directly formed on and at least fully covers the top surface 311 of the encapsulation layer 31, and the chip package structure further includes the light-transmittance layer 51 formed on the top surface 311 of the encapsulation layer 31 and fully covers the fluorescent layer 41. A thickness of the light-transmittance layer 51 is greater than the thickness of the fluorescent layer 41. Additionally, in the second embodiment, the light-transmittance layer 51 has two side surfaces 513 respectively connected with an upper surface 511 of the light-transmittance layer 51, and the two side surfaces 513 of the light-transmittance layer 51 are co-planar with the two side surfaces 313 of the encapsulation layer 31 and the two side surfaces 103 of the substrate 10.

### Third Embodiment

FIG. 4 is a schematic view illustrating a chip package structure according to the third embodiment of the disclosure. In the third embodiment, a light-transmittance layer 52 is further formed on the chip package structure illustrated in FIG. 1D in the same way, but the third embodiment is different from the second embodiment in that the light-transmittance layer 52 of the third embodiment is made of a lens-type transparent plastic material. Referring to FIG. 4, the light-transmittance layer 52 of the third embodiment is formed on the top surface 311 of the encapsulation layer 31 and fully covers the fluorescent layer 41, and an upper surface 521 of the light-transmittance layer 52 extends to the two side surfaces 313 of the encapsulation layer 31.

Either the planar light-transmittance layer 51 (the second embodiment) or the lens-type light-transmittance layer 52 (the third embodiment) is capable of increasing water vapor transmission paths and effectively preventing the water vapor from penetrating in, and the lens-type light-transmittance layer 52 (the third embodiment) may increase the light extraction efficiency.

### Fourth Embodiment

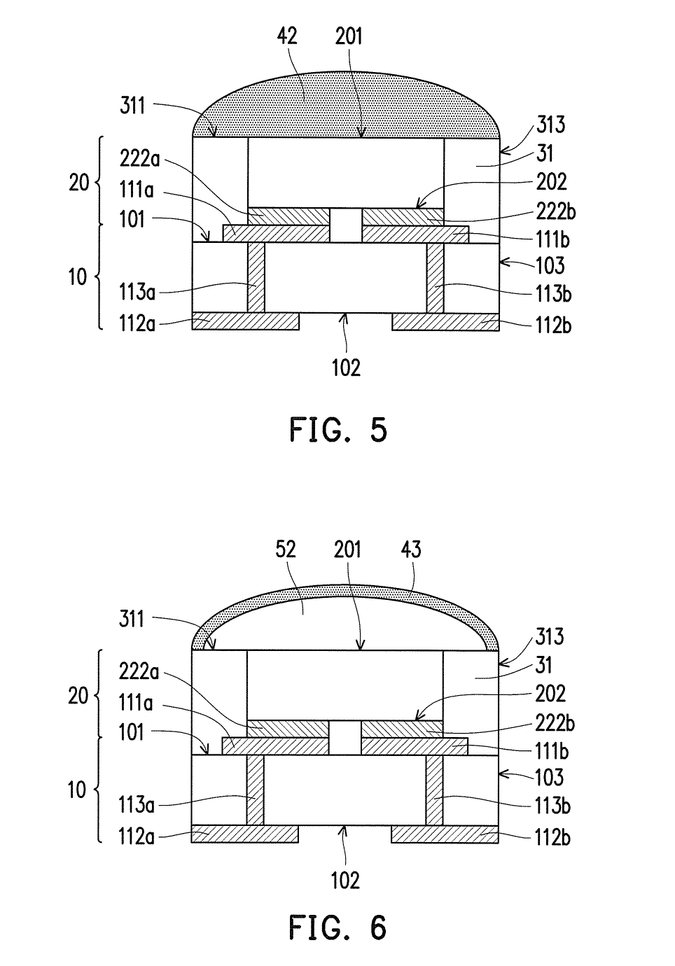

FIG. 5 is a schematic view illustrating a chip package structure according to the fourth embodiment of the disclosure. Being different from the first embodiment, the fluorescent layer 42 of the first embodiment is a planar fluorescent layer, and a fluorescent layer 42 of the fourth embodiment is a lens-type fluorescent layer capable of increasing the light extraction efficiency. In an embodiment, the fluorescent layer 42 contains fluorescence particles having a particle size ranging from 3 μm to 50 μm.

### Fifth Embodiment

FIG. 6 is a schematic view illustrating a chip package structure according to the fifth embodiment of the disclosure. In the fifth embodiment, a lens-type light-transmittance layer 52 is first formed on the top surface 311 of the encapsulation layer 31 and at least fully covers the first surface 201 of the chip 20, and then the fluorescent layer 43 is coated on the lens-type light-transmittance layer 52. The lens-type light-transmittance layer 52 may facilitate not only increasing the water vapor transmission paths to effectively prevent the water vapor from penetrating in, but also increasing the light extraction efficiency.

In addition, in an actual application, a plurality of chips 20 of the embodiment may be disposed on one substrate to form the chip package structure of the embodiment, which may be disposed and laid out in various manners, depending on application requirements. An in-line light source layout and a matrix light source layout are provided below as examples for illustration, but the disclosure is not limited thereto.

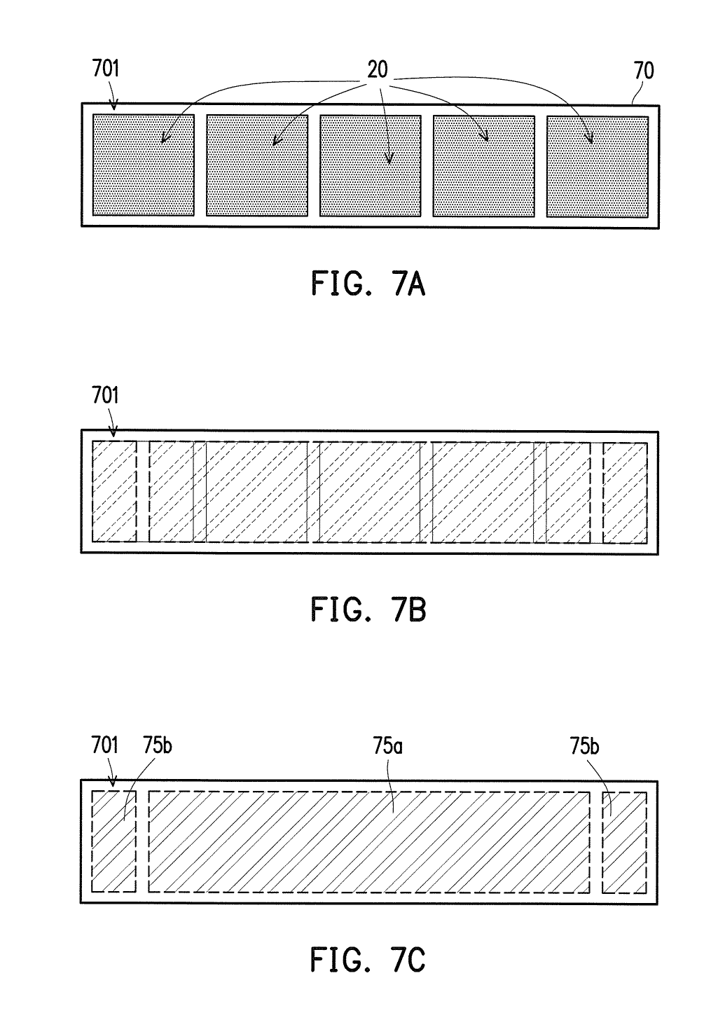

FIGS. 7A to 7C are schematic views showing an application example of the chip package structure in an in-line light source layout on the substrate. A bottom surface 702 of a substrate 70 has thermal pads which may facilitate the entire chip package structure in achieving a heat-electricity separation effect by means of a specific thermal pad design. FIG. 7A illustrates a plurality of (five) chips 20 which are separately disposed on the substrate 70 and arranged in manner like a 1×5 in-line row. FIG. 7B illustrates the chips 20 respectively disposed on a carrier surface 701 of the substrate 70 (of which each block area is, for example, the area of the fluorescent layer 41 of any one of the embodiments above) and disposed on positions of the thermal pads on the bottom surface 702. The carrier surface 701 and the bottom surface 702 of the substrate 70 are conducted with each other through conductive vias. FIG. 7C illustrates thermal pads 75a and 75b located on the bottom surface 702 of the substrate 70. Therein, the thermal pad 75a with large area has an overlapping portion with positions of the corresponding chips 20, and the conductive vias (filled with a conductive material, such as metal) corresponding to the two thermal pads 75b penetrates through the substrate 70 to achieve vertical conduction. During an operation, two opposite voltages are applied to the two thermal pads 75b, and since the thermal pad 75a and the two thermal pads 75b are separately disposed (which radiate the heat independently from each other), this design may achieve heat-electricity separation and extension of the lifespan of the entire package structure.

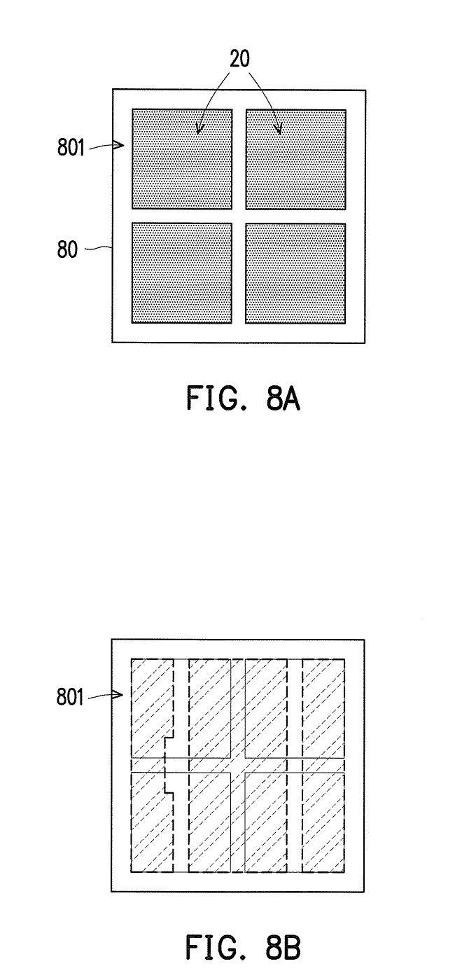

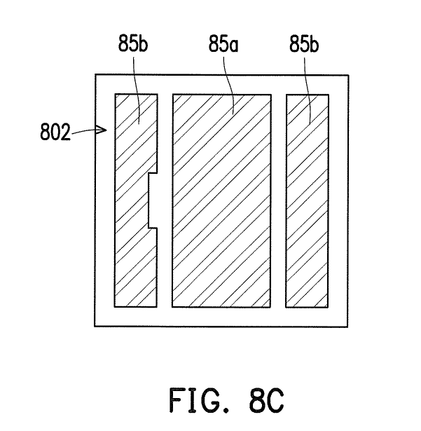

FIGS. 8A to 8C are schematic views showing an application example of the chip package structure in a matrix light source layout on the substrate. Being similar to FIGS. 7A to 7C, FIG. 8A illustrates a plurality of (four) chips which are separately disposed on a substrate 80 and arranged in a manner like a 2×2 matrix. Certainly, the disclosure is not limited thereto, other arrangement manners in m×n matrices (where m≧2, n≧2, m and n are positive integers) may also be applied. FIG. 8B illustrates the chips 20 respectively disposed on a carrier surface 801 of the substrate 80 and on positions of thermal pads on a bottom surface 802. The carrier surface 801 and the bottom surface 802 of the substrate 80 are conducted with each other through conductive vias. FIG. 8C is schematic diagram illustrating a design of thermal pads 85a and 85b disposed on the bottom surface 802 of the substrate 80. Therein, the thermal pad 85a with a large area has an overlapping portion with positions of the corresponding chips 20, and the conductive vias (filled with a conductive material, such as metal) corresponding to the two thermal pads 85b penetrates through the substrate 80 to achieve vertical conduction. During an operation, two opposite voltages are applied to the two thermal pads 85b, and since the thermal pad 85a and the two thermal pads thermal pad 85b are separately disposed (which radiate the heat independently from each other), this design may achieve heat-electricity separation and extension of the lifespan of the entire package structure.

In light of the foregoing, the light-emitting diode (LED) chip package structure (illustrated in FIG. 1D) of the embodiment, the top surface 311 of the encapsulation layer 31 exposes the first surface 201 of the chip 20 and is co-plannar with the first surface 201 (i.e., the light-emitting surface) of the chip 20, the two side surfaces 313 of the encapsulation layer 31 are co-plannar with the two side surfaces 103 of the substrate 10, the fluorescent layer 41 located above the top surface 311 of the encapsulation layer 31 at least fully covers the first surface 201 of the chip 20, but is smaller than one of the side lengths of the encapsulation layer 31, and the area of the fluorescent layer 41 is substantially equal to or greater than the area of each chip 20, but smaller than the area of the top surface 311 of the encapsulation layer 31, thereby mitigating the blue and/or yellow ring phenomenon. In the embodiment, the reflectivity of the encapsulation layer 31 (e.g., including silicon and titanium dioxide) is at least greater than 90%, thereby guiding side light of the chip 20 forward to improving the forward light emitting efficiency and increase the illumination. Moreover, in an embodiment, a ceramic substrate with a low CTE (about 6 ppm/° C.), for example, is selected for the substrate 10 in the same as the material (e.g., a white epoxy or silicon resin encapsulation glue with a low CTE about 14 ppm/° C.) selected for the encapsulation layer 31, such that the structure can be protected from being damaged by the thermal stress. In addition, the ceramic substrate has a high flexural strength and is capable of protecting the chip from being pulled and dragged by the thermal stress, thereby functioning as a stress stopping layer. In addition, through the specific design of the substrate 10 (in which the extending electrodes 111a and 111b and the pads 112a and 112b are conducted with each other), the short circuit risk of the chip package structure of the embodiment may be lowered, and the surface-mount area may be increased when the chip package structure is assembled with the external circuit, such that alignment precision for carrying and assembly efficiency may be improved. In addition, in the coating process of the fluorescent layer 41, a ratio range of phosphors and colloid may be adaptively selected according to different color temperatures, so as to obtain a preferable light conversion and extraction efficiency. In the structural design of the embodiment of the disclosure, the thickness of the fluorescent layer 41 may be correspondingly adjusted and changed based on different demands for the degrees of the color temperatures to be achieved to obtain the preferable light conversion and extraction efficiency. Thus, the design of the chip package structure of the embodiment has greater flexibility for selection in application variations in comparison with the convention chip package structure. Moreover, in the manufacturing method provided according to the embodiment, in the step of forming the encapsulation layer 31 (in which the part of the encapsulation material 30 is removed by means of for example, polishing), the first surface 201 of the chip 20 may further be polished simultaneously, such that the top surface 311 of the encapsulation layer 31 with the high reflectivity is not only co-plannar with the first surface 201 of the chip 20, but also causes the first surface 201 of the chip 20 to form a roughened surface (e.g., having a surface roughness Ra greater than 0.01 μm), so as to increase the light extraction efficiency. In addition, through the carrying of the substrate 10 with high mechanical strength, the chip 20 may further be thinned in the step of roughening the first surface 201 of the chip 20, such that total reflection paths are reduced, and illumination is increased to reinforce the forward light intensity.

It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

### Sixth Embodiment

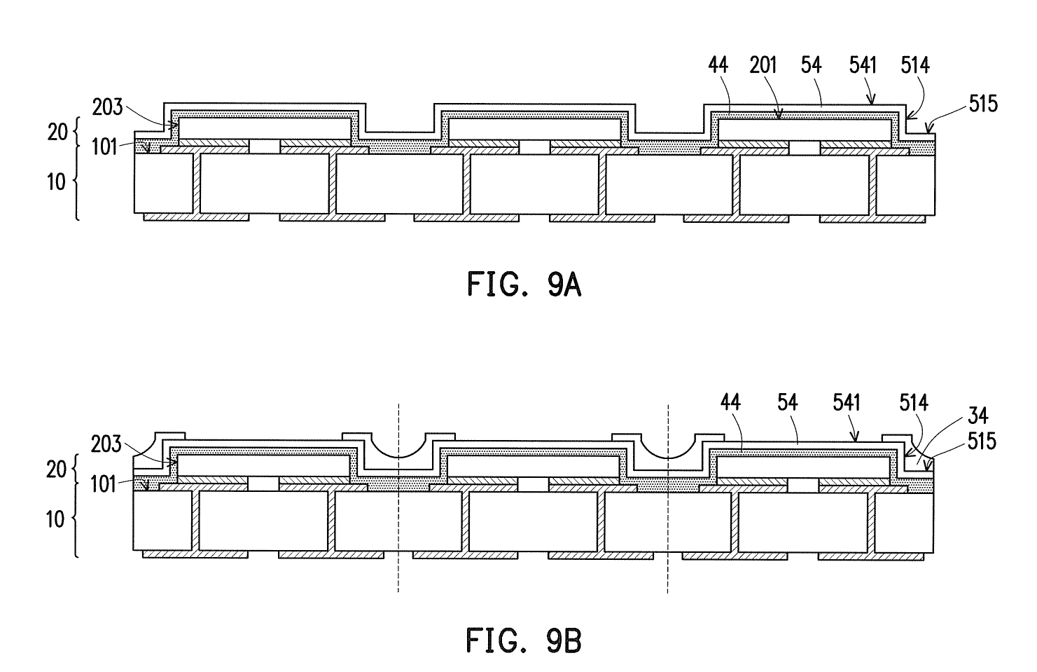

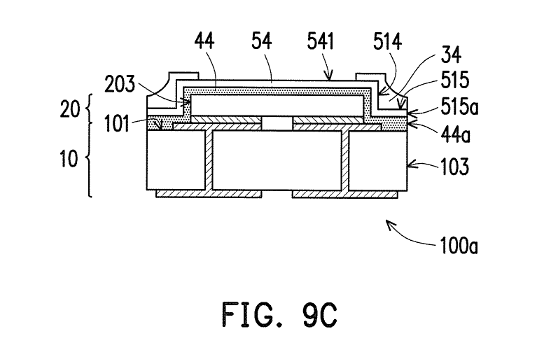

FIGS. 9A to 9C are schematic views illustrating part of the steps of a method of manufacturing a chip package structure according to the sixth embodiment of the disclosure. A method of manufacturing the chip package structure of the present embodiment is similar to that of the embodiment illustrated in FIGS. 2A to 2E, and the difference therebetween merely lies in that after the step illustrated in FIG. 2A, i.e., after the substrate 10 is provided, and the plurality of chips 20 are separately disposed on the carrier surface 101 of the substrate 10, referring to FIG. 9A, a fluorescent layer 44 is formed by means of spraying, and the fluorescent layer 44 directly covers the first surfaces 201 and side surfaces 203 of the chips 20 and the carrier surface 101 of the substrate 10. Then, a light-transmittance layer 54 is formed on the fluorescent layer 44 by means of spraying, wherein the light-transmittance layer 54 is conformal to the fluorescent layer 44 and the light-transmittance layer 54 has an upper surface 541, a plurality of side surfaces 514 respectively connected with the upper surface 541 and a plurality of extending portions 515 connected with the side surface 514. Then, referring to FIG. 9B, an encapsulation layer 34 is formed by means of dispensing, wherein the encapsulation layer 34 extends to and is disposed on the upper surface 541 of the light-transmittance layer 54 along the extending portions 515 and the side surface 514 of the light-transmittance layer 54, and exposes part pf the upper surface 541. In this circumstance, the encapsulation layer 34 directly covers the side surface 514 and the extending portions 515 of the light-transmittance layer 54. Specially, the encapsulation layer 34 covers the side surface 514 and the extending portions 515 of the light-transmittance layer 54 through capillarity, because of the capillarity, extends to and is disposed on the upper surface 541 of the light-transmittance layer 54. Preferably, an extending length of the encapsulation layer 34 on the upper surface 541 of the light-transmittance layer 54 is less than or equal to 10% of the length of the chip 20. However, the encapsulation layer 34 may also present a concaving phenomenon between two adjacent chips 20 due to a surface tension. Afterwards, retelling to FIGS. 9B and 9C simultaneously, the encapsulation layer 34, the light-transmittance layer 54, the fluorescent layer 44 and the substrate 10 are diced to form a plurality of chip package structures. For descriptive convenience, FIG. 9C schematically illustrates only one chip package structure. Referring to FIG. 9C, the two side surfaces 314 of the encapsulation layer 34, side surfaces 515a of the extending portions 515 of the light-transmittance layer 54, side surfaces 44a of the fluorescent layer 44 and the side surfaces 103 of the substrate 10 of each chip package structure are all co-plannar. So far, the manufacture of a chip package structure 100a is completed.

### Seventh Embodiment

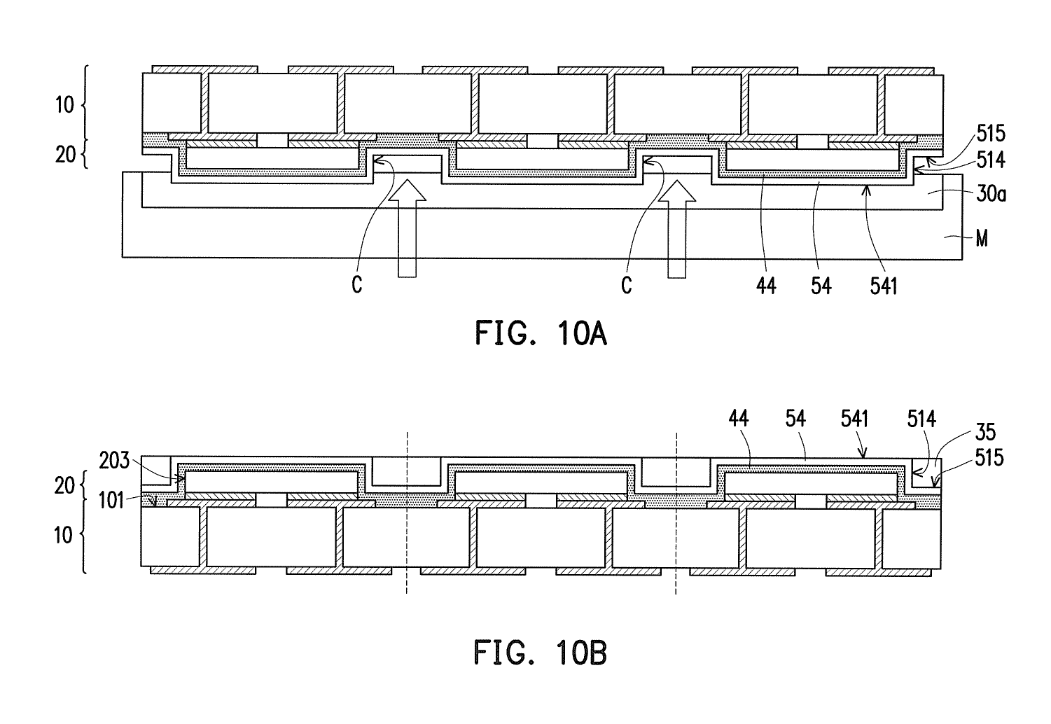

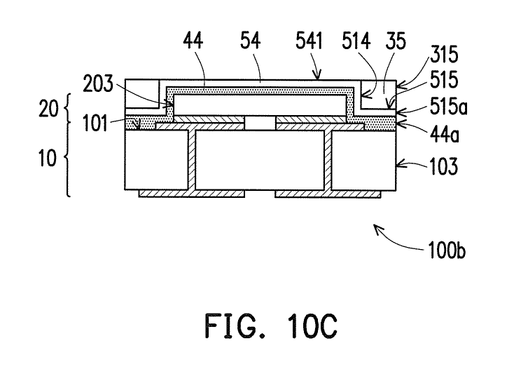

FIGS. 10A to 10C are schematic views illustrating part of the steps of a method of manufacturing a chip package structure according to the seventh embodiment of the disclosure. A method of manufacturing the chip package structure of the present embodiment is similar to that of the embodiment illustrated in FIGS. 9A to 9C, and the difference therebetween merely lies in that after the step illustrated in FIG. 9A, i.e., after the light-transmittance layer 54 is formed, referring the FIG. 10A, the entire structure is turned over, and a mold core M and an encapsulation material 30a disposed on the mold core M is laminated on the light-transmittance layer 54 by means of heating and pressing. Since both the light-transmittance layer 54 and the fluorescent layer 44 are conformal to the outer contour of the chip 20, a cavity C is provided between two adjacent two adjacent chips 20, and the encapsulation material 30a is filled therein due to the thermal lamination. Then, referring to FIG. 10B, the mold core M is removed, and the entire structure is turned over to form an encapsulation layer 35. In this circumstance, the encapsulation layer 35 totally exposes the upper surface 541 of the light-transmittance layer 54, and a concentration of the encapsulation layer 35 in the cavity C is greater than that on the upper surface 541 of the light-transmittance layer 54. Thereafter, referring to FIGS. 10B and 10C simultaneously, the encapsulation layer 35, the light-transmittance layer 54, the fluorescent layer 44 and the substrate 10 are diced to form a plurality of chip package structures. For descriptive convenience, FIG. 10C schematically illustrates only one chip package structure. Referring to FIG. 10C, side surfaces 315 of the encapsulation layer 35, the side surfaces 515a of the extending portions 515 of the light-transmittance layer 54, the side surfaces 44a of the fluorescent layer 44 and the side surfaces 103 of the substrate 10 of each chip package structure are all co-plannar. So far, the manufacture of a chip package structure 100b is completed.

### Eighth Embodiment

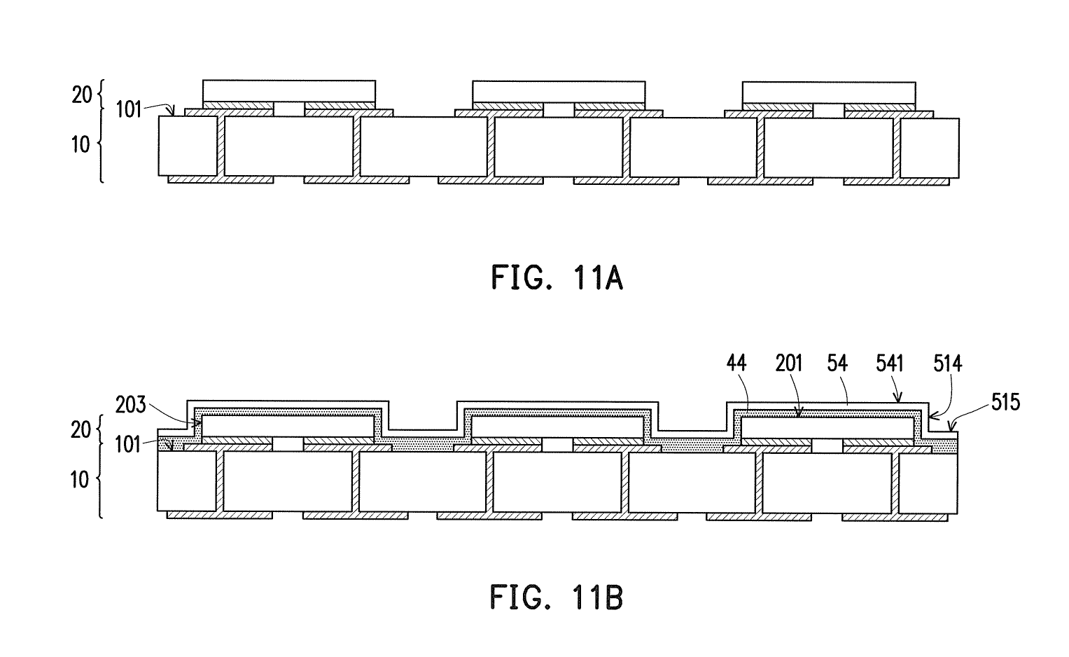

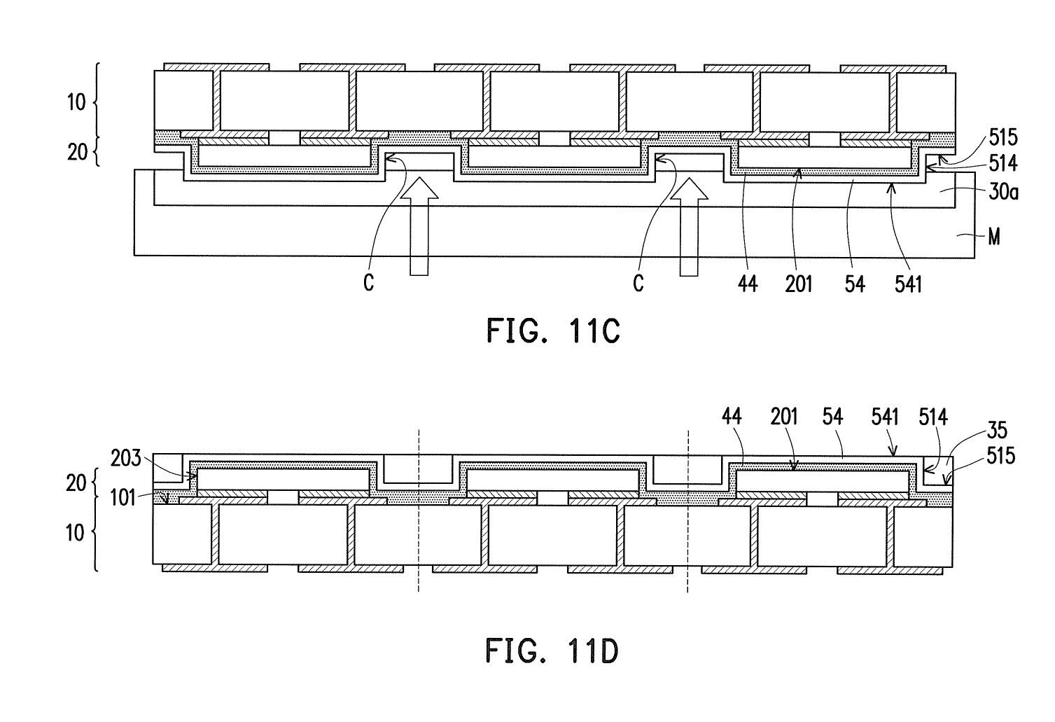

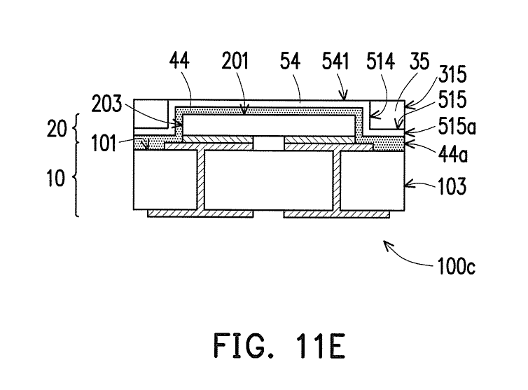

FIGS. 11A to 11C are schematic views illustrating part of the steps of a method of manufacturing a chip package structure according to the eighth embodiment of the disclosure. A method of manufacturing the chip package structure of the present embodiment is similar to that of the embodiment illustrated in FIGS. 2A to 2E, and the difference therebetween merely lies in that after the step illustrated in FIG. 2C, i.e., after the part of the encapsulation material 30 is removed by means of polishing to form the encapsulation layer 31, steps, such as roughening one surface (e.g., the first surface 201) of the chip 20 and thinning the chip 20 may further be performed during the polishing operation, after the polishing operation is completed, the top surface 311 of the encapsulation layer 31 exposes the first surface 201 of the chip 20, and referring to FIG. 11A, the encapsulation layer 31 is removed after being co-plannar with the first surface 201 of the chip 20. In this case, the purpose of the steps of roughening the first surface 201 of the chip 20 and thinning the chip 20 is to make the chips 20 having the same height in favor of the subsequent manufacturing steps. Then, referring to FIG. 11B, a fluorescent layer 44 is formed by means of spraying, and the fluorescent layer 44 directly covers the first surface 201 and the side surfaces 203 of the chip 20 and the carrier surface 101 of the substrate 10. Thereafter, a light-transmittance layer 54 is formed on the fluorescent layer 44 by means of spraying, wherein the light-transmittance layer 54 is conformal to the fluorescent layer 44 and has an upper surface 541, a plurality of side surfaces 514 respectively connected with the upper surface 541 and a plurality of extending portions 515 connected with the side surfaces 514. Then, referring to FIG. 11C, the entire structure is turned over, a mold core M and an encapsulation material 30a disposed on the mold core M is laminated on the light-transmittance layer 54 by means of heating and pressing. Since both the light-transmittance layer 54 and the fluorescent layer 44 are conformal to the outer contour of the chip 20, a cavity C is provided between two adjacent two adjacent chips 20, and the encapsulation material 30a is filled therein due to the thermal lamination. A concentration of the encapsulation material 30a in the cavity C is greater than that on the upper surface 541 of the light-transmittance layer 54. Thereafter, referring to FIG. 11D, the mold core M is removed, and the entire structure is turned over to form the encapsulation layer 35. In this circumstance, the encapsulation layer 35 totally exposes the upper surface 541 of the light-transmittance layer 54. Thereafter, referring to FIGS. 11D and 11E simultaneously, the encapsulation layer 35, the light-transmittance layer 54, the fluorescent layer 44 and the substrate 10 are diced to form a plurality of chip package structures. For descriptive convenience, FIG. 11E schematically illustrates only one chip package structure. Referring to FIG. 11E, the side surfaces 315 of the encapsulation layer 35, the side surfaces 515a of the extending portions 515 of the light-transmittance layer 54, the side surfaces 44a of the fluorescent layer 44 and the side surfaces 103 of the substrate 10 of each chip package structure are all co-plannar. So far, the manufacture of a chip package structure chip package structure 100c is completed.

### Ninth Embodiment

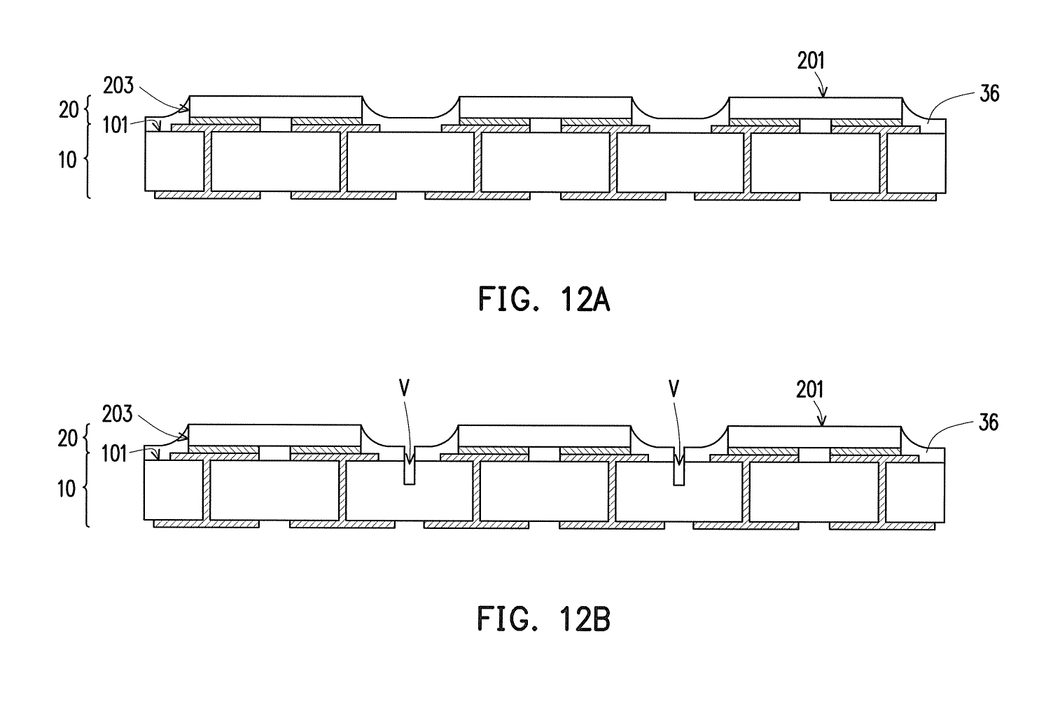

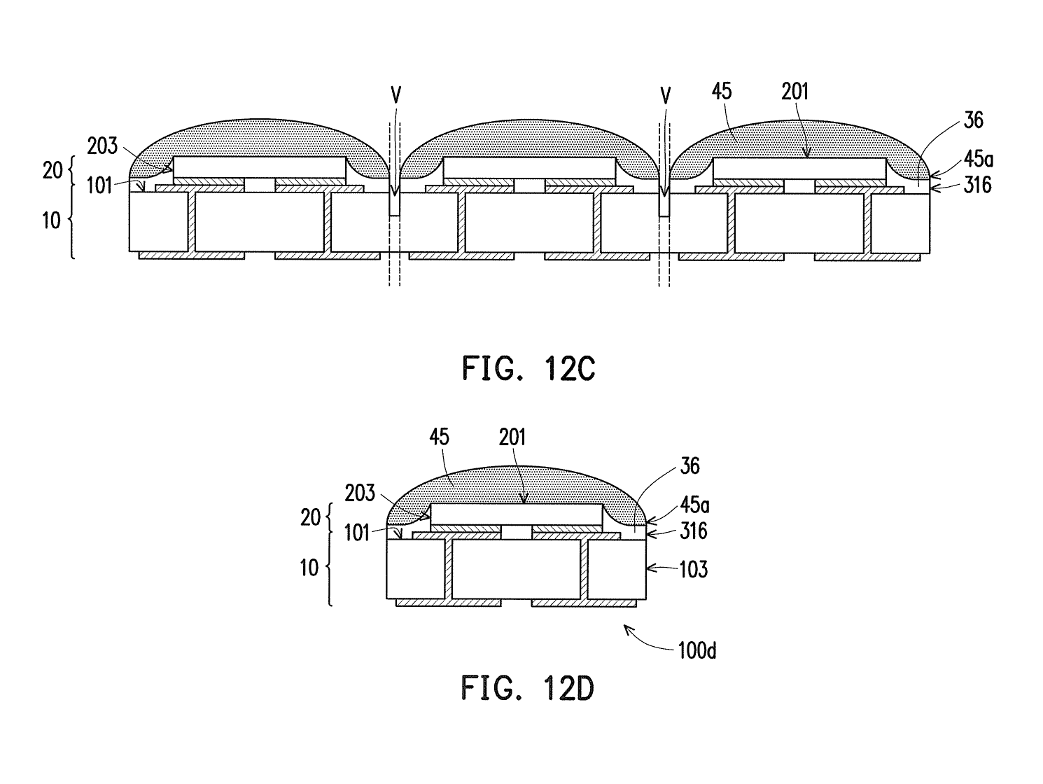

FIGS. 12A to 12D are schematic views illustrating part of the steps of a method of manufacturing a chip package structure according to the ninth embodiment of the disclosure. A method of manufacturing the chip package structure of the present embodiment is similar to that of the embodiment illustrated in FIGS. 2A to 2E, and the difference therebetween merely lies in that after the step illustrated in FIG. 2A, i.e., after the substrate 10 is provided, and the chips 20 are separately disposed on the carrier surface 101 of the substrate 10, referring to FIG. 12A, an encapsulation layer 36 is formed by means of dispensing, wherein the encapsulation layer 36 extends to and is disposed on the carrier surface 101 of the substrate 10 along the side surfaces 203 of the chips 20. Then, referring to FIG. 12B, a pre-dicing process is performed on the encapsulation layer 36 and the substrate 10 to form a plurality of grooves V. Then, referring to FIG. 12C, a fluorescent layer 45 is formed on the first surface 201 of the chip 20 by means of dispensing, extends to and covers the encapsulation layer 36. In this case, the fluorescent layer 45 is a lens-type fluorescent layer. Thereafter, referring to FIG. 12D, the substrate 10 is diced along the grooves V to form a plurality of chip package structures. For descriptive convenience, FIG. 12D schematically illustrates only one chip package structure. Referring to FIG. 12D, side surfaces 316 of the encapsulation layer 36, the side surface 45a of the fluorescent layer 45 and the side surfaces 103 of the substrate 10 of each chip package structure are all co-plannar. So far, the manufacture of a chip package structure 100d is completed.

In light of the foregoing, the disclosure provides a chip package structure and a method of manufacturing the same, in which after the chip is disposed on the substrate and packaged by the encapsulation layer, one of the surfaces of the chip is exposed, and then the fluorescent layer is formed on the exposed surface of the chip. Through the designs of the embodiments, the optical properties, for example, the light conversion and extraction efficiency, of the chip package structure can be improved. In other embodiments, the light-transmittance layer may be further selectively disposed on the fluorescent layer to serve as a light-transmittance protective layer, such that water vapor transmission paths can be increased, and the water vapor can be effectively prevent from penetrating in. Certainly, different structure types of the light-transmittance layer (for example, a lens light-transmittance layer) can facilitate effectively improving the light extraction efficiency.

Although the disclosure has been disclosed by the above embodiments, they are not intended to limit the disclosure. It will be apparent to one of ordinary skill in the art that modifications and variations to the disclosure may be made without departing from the spirit and scope of the disclosure. Therefore, the scope of the disclosure will be defined by the appended claims.

What is claimed is:

1. A chip package structure, comprising:
a substrate, having a carrier surface;
a chip, having a first surface and a second surface which are opposite to each other and a side surface connecting the first surface and the second surface, wherein the second surface of the chip is disposed on the carrier surface of the substrate;
a fluorescent layer, fully covering the first surface of the chip; and
an encapsulation layer, covering the carrier surface of the substrate and the side surface of the chip, wherein a reflectivity of the encapsulation layer is at least greater than 90%.

2. The chip package structure as claimed in claim 1, wherein the encapsulation layer directly covers the carrier surface of the substrate and encapsulates the side surface of the chip, a top surface of the encapsulation layer exposes the first surface of the chip and is co-plannar with the first surface of the chip, the fluorescent layer is located on the top surface of the encapsulation layer, and a first side length of the fluorescent layer is shorter than a second side length of the encapsulation layer.

3. The chip package structure as claimed in claim 2, wherein the substrate has two side surfaces respectively connected with the carrier surface, the encapsulation layer has two side surfaces respectively connected with the top surface, and the two side surfaces of the encapsulation layer are co-plannar with the two side surfaces of the substrate.

4. The chip package structure as claimed in claim 1, wherein the chip comprises a plurality of electrodes separately disposed on the second surface, and the substrate comprises a plurality of extending electrodes disposed on the carrier surface and respectively contacting the electrodes of the chip, wherein the encapsulation layer also covers the electrodes and the extending electrodes.

5. The chip package structure as claimed in claim 4, wherein the substrate has a bottom surface opposite to the carrier surface and further has a plurality of pads separately disposed on the bottom surface and a plurality of conductive vias vertically formed in the substrate, wherein the pads and the extending electrodes are electrically connected through the conductive vias.

6. The chip package structure as claimed in claim 4, wherein each adjacent electrodes of the chip have a first spacing, each adjacent pads of the substrate have a second spacing, and the second spacing is greater than the first spacing.

7. The chip package structure as claimed in claim 2, wherein the fluorescent layer is directly formed on the top surface of the encapsulation layer and at least fully covers the first surface of the chip, wherein the chip package structure further comprises:
a light-transmittance layer, formed on the top surface of the encapsulation layer and fully covers the fluorescent layer, wherein a thickness of the light-transmittance layer is greater than a thickness of the fluorescent layer.

8. The chip package structure as claimed in claim 7, wherein the substrate has two side surfaces respectively connected with the carrier surface, the encapsulation layer has two side surfaces respectively connected with the top surface, and the light-transmittance layer has an upper surface extending to the two side surfaces of the encapsulation layer.

9. The chip package structure as claimed in claim 8, wherein the light-transmittance layer has two side surfaces respectively connected with the upper surface, and the two side surfaces of the encapsulation layer, the two side surfaces of the substrate and the two side surfaces of the light-transmittance layer are all co-plannar.

10. A method of manufacturing a chip package structure, comprising:
providing a substrate having a carrier surface;
disposing a plurality of chips separately on the carrier surface of the substrate, wherein each of the chips has a first surface and a second surface which are opposite to each other and a side surface connecting the first surface and the second surface, and the second surfaces are disposed on the carrier surface of the substrate;
forming a fluorescent layer to fully cover the first surfaces of the chips;
forming an encapsulation layer to cover the carrier surface of the substrate and the side surfaces of the chips, wherein a reflectivity of the encapsulation layer is at least greater than 90%; and
dicing the encapsulation layer and the substrate to form a plurality of chip package structures.

11. The method of manufacturing the chip package structure as claimed in claim 10, wherein the encapsulation layer is formed before the fluorescent layer, and the step of forming the encapsulation layer and the fluorescent layer comprises:
forming an encapsulation material on the carrier surface of the substrate to cover the earlier surface and the side surfaces of the chips;
removing part of the encapsulation material to form the encapsulation layer, wherein a top surface of the encapsulation layer exposes the first surfaces of the chips and is co-plannar with the first surfaces of the chips;
providing a mask above the encapsulation layer, wherein the mask has a plurality of openings which are separately disposed and corresponding to positions of the chips; and
coating the fluorescent layer on the top surface of the encapsulation layer through the openings of the mask, such that the fluorescent layer fully covers the first surfaces of the chips.

12. The method of manufacturing the chip package structure as claimed in claim 11, wherein in the step of forming the encapsulation layer, the part of the encapsulation material is removed by means of polishing to form the encapsulation layer, the first surfaces of the chips are also polished, the first surfaces of the chips after being polished have a center-line average roughness greater than 0.01 μm, and the top surface of the encapsulation layer is co-plannar with the first surfaces of the chips.

13. The method of manufacturing the chip package structure as claimed in claim 11, wherein after the step of coating the fluorescent layer on the top surface of the encapsulation layer, the method further comprises:
removing the mask and forming a light-transmittance layer on the top surface of the encapsulation layer, wherein the light-transmittance layer fully covers the fluorescent layer on each of the chips, a thickness of the light-transmittance layer is greater than a thickness of the fluorescent layer, and in the step of dicing, the light-transmittance layer, the encapsulation layer and the substrate are diced to form the chip package structures.

14. The method of manufacturing the chip package structure as claimed in claim 10, wherein a first side length of the fluorescent layer of each of the chip package structures is shorter than a second side length of the encapsulation layer.

15. The method of manufacturing the chip package structure as claimed in claim 10, wherein the substrate has a bottom surface opposite to the carrier surface, and the substrate comprises:
a plurality of extending electrodes separately disposed on the carrier surface;
a plurality of pads separately disposed on the bottom surface; and
a plurality of conductive vias vertically formed in the substrate, and the pads and the extending electrodes are electrically connected through the conductive vias, wherein each of the chips comprises a plurality of electrodes separately disposed on the second surface, and when the chips are disposed on the carrier surface of the substrate, the electrodes of the chips respectively contact the extending electrodes of the substrate.

16. The method of manufacturing the chip package structure as claimed in claim 15, wherein each adjacent electrodes of the chip have a first spacing, each adjacent pads of the substrate have a second spacing, and the second spacing is greater than the first spacing.

17. The method of manufacturing the chip package structure as claimed in claim 10, further comprising:
forming a light-transmittance layer on the first surfaces of the chips to cover the first surfaces and then coating the fluorescent layer on the light-transmittance layer.

18. The method of manufacturing the chip package structure as claimed in claim 10, wherein the fluorescent layer is formed before the encapsulation layer, and the fluorescent layer directly covers the first surfaces and the side surfaces of the chips and the carrier surface of the substrate by means of spraying.

19. The method of manufacturing the chip package structure as claimed in claim 10, further comprising:
forming a light-transmittance layer on the fluorescent layer after the step of forming the fluorescent layer and before the step of forming the encapsulation layer, wherein the light-transmittance layer is conformal to the fluorescent layer, and the light-transmittance layer has an upper surface, a plurality of side surfaces respectively connected with the upper surface and a plurality of extending portions connected with the side surfaces; and
when forming the encapsulation layer, directly covering the side surfaces and the extending portions of the light-transmittance layer by the encapsulation layer.

20. The method of manufacturing the chip package structure as claimed in claim 10, wherein the fluorescent layer is formed after the encapsulation layer and the step of dicing the encapsulation layer and the substrate comprises:
performing a pre-dicing process on the encapsulation layer and the substrate to form a plurality of grooves after the step of forming the encapsulation layer and before the step of forming the fluorescent layer; and
dicing the substrate along the grooves to form the chip package structures.
